(19) United States
(12) Patent Application Publication
(10) Pub. No.: US 2009/0207678 A1
(43) Pub. Date: Aug. 20, 2009

(54) Memory writing interference test system and method thereof

(76) Inventors: Chih-Wei Chen, Taipei City (TW); Hsiao-Fen Lu, Taipei City (TW)

Correspondence Address: Chih Feng Yeh;BRIAN M. MCINNIS, 12th Floor, Ruttonjee House, 11 Duddell Street, Hong Kong, HK

(21) Appl. No.: 12/213,032

(22) Filed: Jun. 13, 2008

(30) Foreign Application Priority Data
Feb. 20, 2008 (TW) 97105971

(51) Int. Cl. G11C 29/00; G11C 7/00; G11C 8/00

(52) U.S. Cl. 365/201; 365/230.03; 365/239

(57) ABSTRACT

The present invention is a memory writing interference test system and method thereof. The test system comprises a memory, a progressing unit, a write-in unit, a read-out unit, and a discriminating unit. By sequentially writing data and then reading out the written data from one memory block after one through the whole memory, determines if the memory has the memory writing interference.

### RELATED APPLICATIONS

This application claims priority to Taiwan Application Serial Number 97105971, filed Feb. 20, 2008, which is herein incorporated by reference.

### BACKGROUND

1. Field of Invention

The present invention relates to a memory writing interference test system and method thereof. More particularly, the present invention relates to a system and method for determining the defective memories of memory writing interference.

2. Description of Related Art

In general memory testing, specific data is written into the memory of a computer with a certain address, and the data is read out and stored in the memory to be compared with the written data. When writing data into one memory block of a certain address in a defective memory, the interference to the writing occurs and the data is stored in some other memory blocks.

Writing interference tests in the prior art requires reading the data stored in the entire memory module after the data used for comparison has been written into a single memory block. Therefore, much more time is needed to compare data stored in the entire memory module.

### SUMMARY

For this reason, the present invention provides a memory writing interference test system and method thereof. By back and forth writing in and reading out data from each memory block in the memory sequentially, and discriminating if the data stored in each memory block is null, the test system and method is applied to determine the defective memory with memory writing interference.

The main idea of this invention is to provide a memory writing interference test method. The test method provides for determining the defective memory with memory writing interference by sequentially writing a specific pattern into the memory blocks from the memory block at an initial section, and then reading the next memory block to discriminate if data stored in the memory block is null.

The other idea of this invention is to provide a memory writing interference test system, comprising a memory, having plural memory blocks wherein each of the memory blocks has an effective address; a progressing unit, sequentially pointing to the effective addresses of the memory blocks to be examined one by one; a write-in unit, writing a specific pattern into the memory block according to the effective address pointed at by the progressing unit; a read-out unit, reading out data in the succeeding memory block next to the effective address; and a discriminating unit, discriminating if the data read out by the read-out unit is null, and determining the corresponding results.

By the memory writing interference test system and method of this invention, different memory blocks in the memory module is tested to judge if having memory writing interference. That is, after writing data into a certain memory block, the system and method is applied to examine if the preceding memory block or the succeeding memory block is interfered with when the data is written. And when examining the memory block, only one memory block is focused on. Therefore, by this invention, the memory writing interference test can be determined in a short period of time, thus improves the testing technique in prior art.

### BRIEF DESCRIPTION OF THE DRAWINGS

The invention can be more fully understood by reading the following detailed description of the embodiment, with reference made to the accompanying drawings as follows:

FIG. 1 is the block diagram of the memory writing interference test system of this invention;

FIGS. 2A and 2B illustrate the tests of the memory writing interference of this invention; and

FIGS. 3A and 3B are the flowcharts of the memory writing interference test method of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

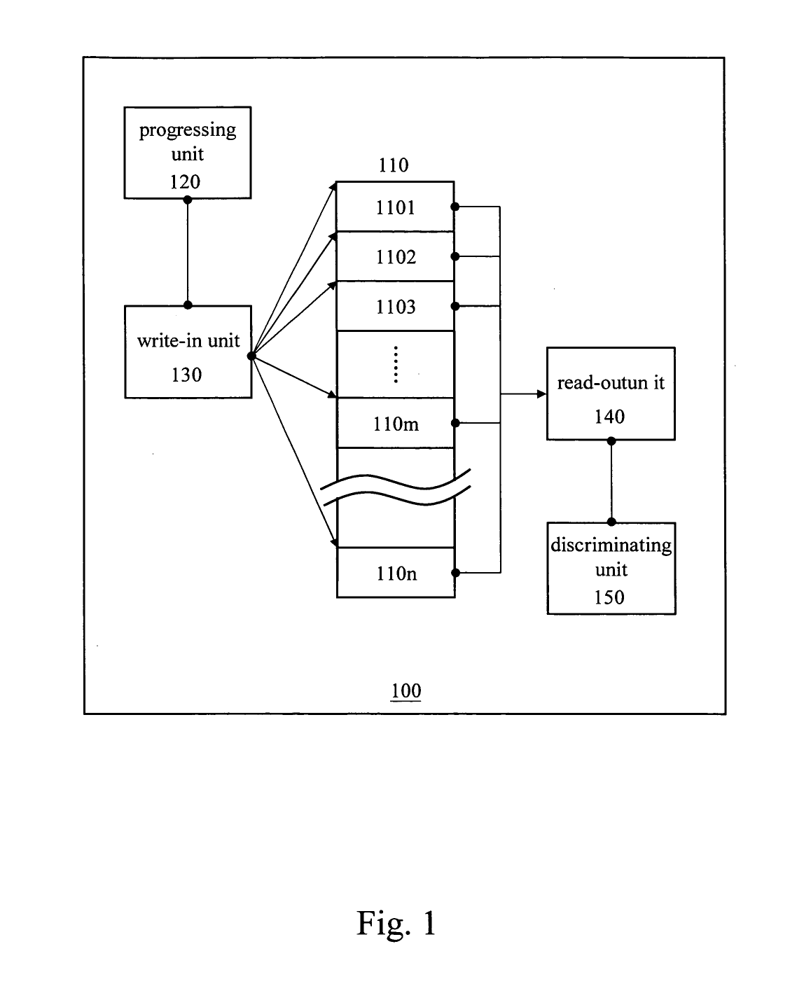

Refer to FIG. 1. FIG. 1 is the block diagram of the memory writing interference test system of this invention. As shown in FIG. 1, the present invention provides a memory writing interference test system 100, comprising a memory module 110, a progressing unit 120, a write-in unit 130, a read-out unit 140, and a discriminating unit 150. The memory module 110 has plural memory blocks, 1101˜110n, and each of the memory blocks has an effective address. The progressing unit 120 sequentially points to the effective address of the memory block 1101˜110n to be examined one by one. The write-in unit 130 provides for writing a specific pattern, such as characters “AA”, into the memory block 1101˜110n according to the effective address pointed to by the progressing unit 120. The read-out unit 140 provides reads out data stored in the succeeding memory block next to the effective address. And the discriminating unit 150 provides for discriminating whether the data read out by the read-out unit 140 is null or not, and determining the corresponding results. When the discriminating unit 150 discriminates the data stored in one of the memory blocks is not null, the memory module is determined having the memory writing interference.

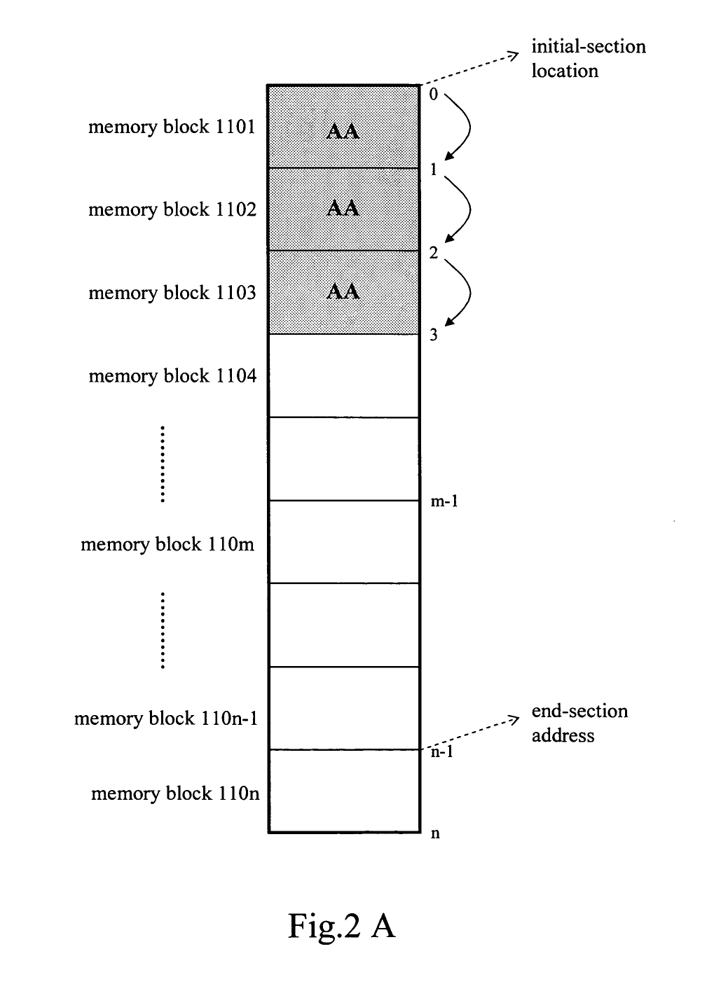

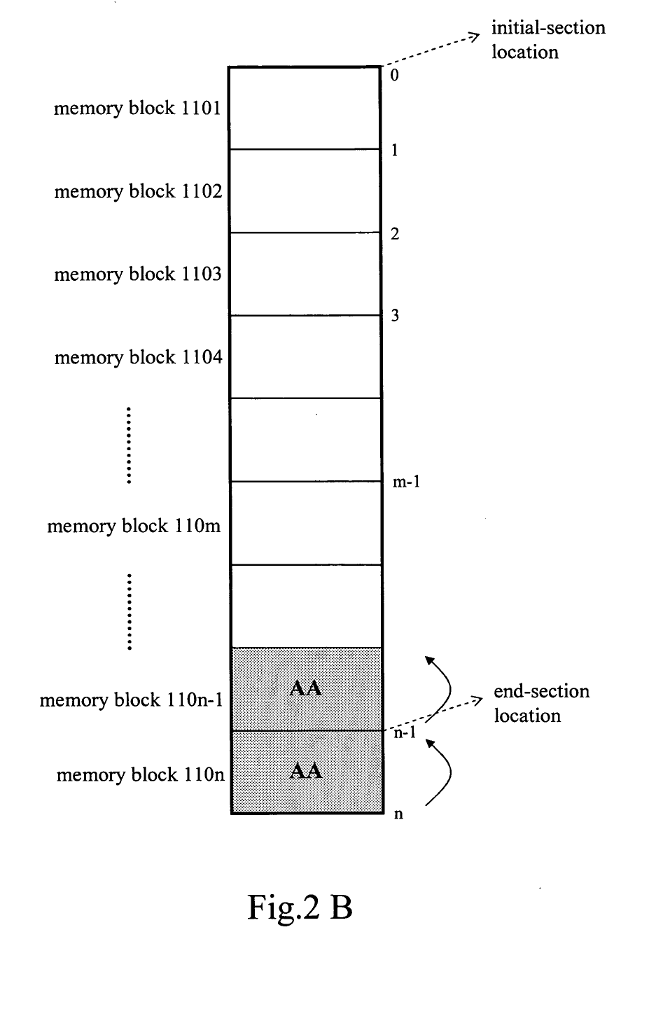

Refer to FIGS. 2A and 2B. FIGS. 2A and 2B illustrate the tests of the memory writing interference of this invention. The above-mentioned progressing unit 120 comprises a means for sequentially pointing to the effective addresses of the memory block 1101˜110n from an initial-section location to an end-section location (as shown in FIG. 2A), and sequentially pointing to the effective addresses of the memory block 1101˜110n from the end-section location to the initial-section location (as shown in FIG. 2B). And wherein the initial-section location is a start address of the first memory block 1101 in the memory module 110, and the end-section location is a start address of the last memory block 110n in the memory module 110.

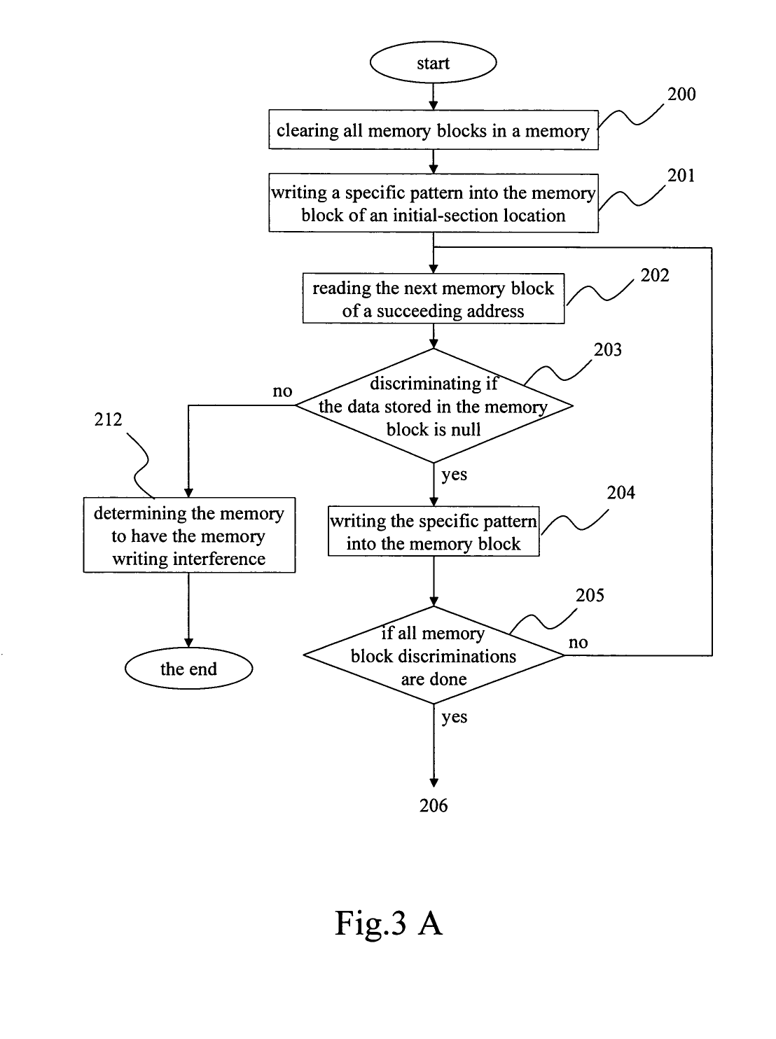

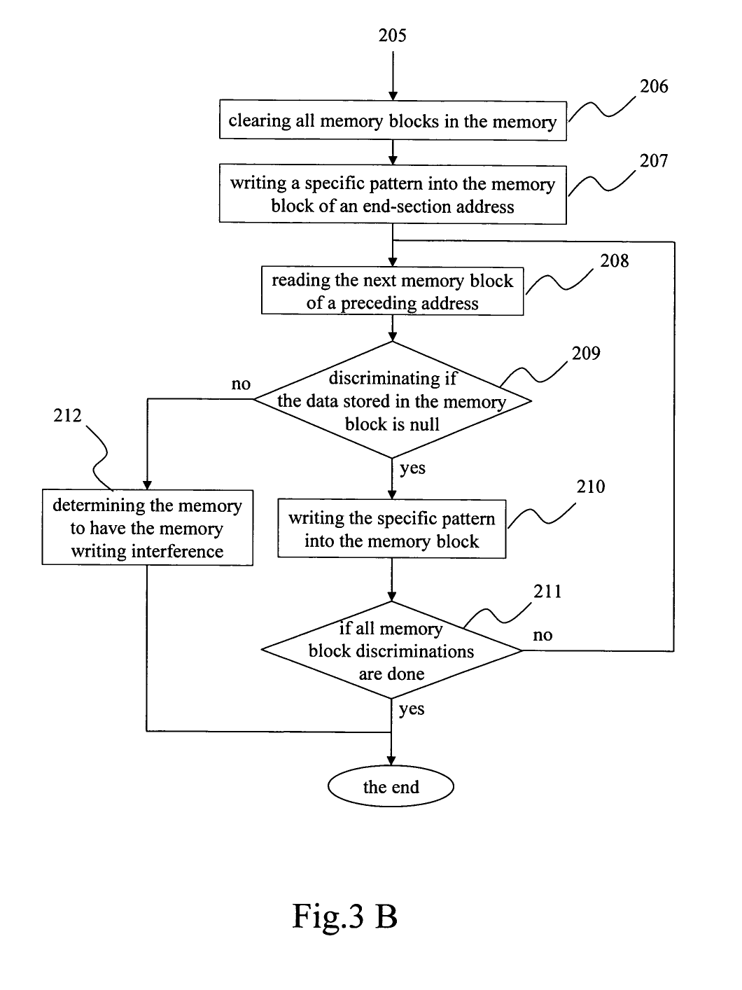

The memory writing interference test method of this invention, applies writing in and reading out the memory blocks in two directions, and by discriminating the data stored in the memory block to determine the memory with the memory writing interference. The test procedure is divided into two phases. In the first phase, as shown in FIG. 3A, data stored in all memory blocks in memory module 110 is cleared (Step 200). Then, a specific pattern, such as characters “AA”, is written into the memory blocks 1101 of an initial-section location (Step 201). Then, the read-out unit 140 reads the next memory block 110m (m=2˜n−1) of the succeeding address (Step 202). And the discriminating unit 150 discriminates if the data stored in memory block 110m is null (Step 203). If the data stored in memory block 110m is not null, it means one of the memory blocks in memory module 110 has been interfered with when data was written into the memory module 110. Thus the memory module 110 is determined to have been interfered with when data was being written to the memory module 110 (Step 212). But if the data stored in memory block 110m is discriminated null in Step 203, the write-in unit 130 keeps writing the specific pattern into memory block 1101˜110n in sequence (Step 204). Following Step 204, all memory blocks are checked to ensure discriminations are done (Step 205). If all memory block discriminations are not finished, the procedure returns to Step 202 to read the next memory block 110m of a succeeding address. Till the last memory block 110n at the end-section location is discriminated and found that no interference during the memory writing stage occurred, the test procedure then goes to the second phase.

In the second phase, as shown in FIG. 3B, first any data stored in all the memory blocks in the memory module 110 is cleared (Step 206). Then, the specific pattern “M” is written into the memory block 110n of an end-section location (Step 207). Then, the read-out unit 140 reads the next memory block 110m (m=2˜n−1) of a preceding address (Step 208). And the discriminating unit 150 discriminates if the data stored in memory block 110m is null (Step 209). If the data stored in memory block 110m is not null, it means interference to one of the memory blocks in the memory module 110 occurred when data was being written into the memory module 110. Thus the memory module 110 is determined to have been interfered with when data was being written to the memory module 110 (Step 212). But if the data stored in the memory block 110m is discriminated null in Step 209, the write-in unit 130 keeps writing the specific pattern into memory block 1101˜110n in sequence (Step 210). Following Step 210, all memory blocks are checked to ensure discriminations are done (Step 211). If all memory blocks discriminations are not finished, the procedure returns to Step 208 to read the next memory block 110m of a preceding address. Till the last memory block 1101 at the initial-section location is discriminated and found that no interference during the memory writing stage occurred, the whole test procedure of this invention is finished. Wherein the above-mentioned initial-section location is the start address of the first memory block 1101 in the memory module 110, and the end-section location is the start address of the last memory block 110n in the memory module 110.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A memory writing interference test system, comprising:
a memory module having plural memory blocks wherein each of the memory blocks has an effective address;
a progressing unit pointing sequentially to the effective addresses of the memory blocks to be examined one by one;
a write-in unit writing a specific pattern into the memory block according to the effective address pointed by the progressing unit;
a read-out unit reading out data in the succeeding memory block next to the effective address; and
a discriminating unit discriminating if the data read out by the read-out unit is null, and determining corresponding results.

2. The test system of claim 1, wherein the progressing unit comprises means for sequentially pointing to the effective addresses of the memory blocks from an initial-section location to an end-section location, and sequentially pointing to the effective addresses of the memory blocks from the end-section location to the initial-section location.

3. The test system of claim 2, wherein the initial-section location is a start address of the first memory block in the memory module.

4. The test system of claim 2, wherein the end-section location is a start address of the last memory block in the memory module.

5. The test system of claim 1, whereof the discriminating unit when discriminates the data stored in the memory block is not null, the memory module is determined having the memory writing interference.

6. A memory writing interference test method, comprising following steps:
clearing all memory blocks in a memory module;
writing a specific pattern into the memory blocks in sequence starting from the memory block at an initial-section location;
reading a next memory block of a succeeding address; and
discriminating if data stored in the memory block of the succeeding address is null.

7. The test method of claim 6, wherein the step of writing a specific pattern into memory blocks in sequence further comprises means for pointing to each address of the memory blocks sequentially from the initial-section location to the end-section location.

8. The test method of claim 7, wherein the initial-section location is a start address of the first memory block in the memory module, and the end-section location is a start address of the last memory block in the memory module.

9. The test method of claim 6, wherein the step of discriminating if data stored in the succeeding memory block is not null, then the memory module is determined to have the memory writing interference.

10. The test method of claim 6, further comprising following steps:
clearing all memory blocks in the memory block;
writing the specific pattern into memory blocks in sequence starting from the memory block at the end-section location;
reading the next memory block of a preceding address; and
discriminating if data stored in the memory block of preceding address is null.

11. The test method of claim 10, wherein the step of writing the specific pattern into memory blocks in sequence further comprises a means for pointing to each address of the memory blocks sequentially from the end-section location back to the initial-section location.

12. The test method of claim 11, wherein the initial-section location is a start address of the first memory block in the memory module, and the end-section location is a start address of the last memory block in the memory module.

13. The test method of claim 10, wherein the step of discriminating if data stored in the preceding memory block is not null, then the memory module is determined to have the memory writing interference.

14. A memory writing interference test method, comprising the following steps:
clearing all memory blocks in a memory module;
writing a specific pattern into the memory blocks in sequence starting from the memory block at an initial-section location;
reading a next memory block of a succeeding address;
discriminating if data stored in the memory block of the succeeding address is null;
writing the specific pattern into memory blocks in sequence starting from the memory block at an end-section location;
reading the next memory block of a preceding address; and
discriminating if data stored in the memory block of preceding address is null.

15. The test method of claim 14, wherein the step of writing the specific pattern into the memory blocks in sequence starting from the memory block at an initial-section location further comprises means for pointing to each address of the memory blocks sequentially from the initial-section location to the end-section location.

16. The test method of claim 15, wherein the initial-section location is a start address of the first memory block in the memory module, and the end-section location is a start address of the last memory block in the memory module.

17. The test method of claim 14, wherein the step of writing the specific pattern into memory blocks in sequence starting from the memory block at an end-section location further comprises a means for pointing to each address of the memory blocks sequentially from the end-section location to the initial-section location.

18. The test method of claim 17, wherein the initial-section location is a start address of the first memory block in the memory module, and the end-section location is a start address of the last memory block in the memory module.

19. The test method of claim 14, wherein the step of discriminating if data stored in the succeeding memory block is not null, then the memory module is determined to have the memory writing interference.
